(19) United States
(12) Patent Application Publication
(10) Pub. No.: US 2026/0293486 A1
(43) Pub. Date: Sep. 24, 2026

(54) DISPLAY PANEL AND DISPLAY DEVICE

(71) Applicant: BOE TECHNOLOGY GROUP CO., LTD., Beijing (CN)

(72) Inventor: Jing Yang, Beijing (CN)

(73) Assignee: BOE TECHNOLOGY GROUP CO., LTD., Beijing (CN)

(21) Appl. No.: 19/479,842

(22) PCT Filed: May 29, 2024
(86) PCT No.: PCT/CN2024/096097

§ 371 Date: Oct. 29, 2025

(30) Foreign Application Priority Data
Jun. 19, 2023 (CN) 202310729185.9

(51) Int. Cl. H10K 59/38; H10K 59/122; H10K 59/40; H10K 59/80; H10K 102/00

(52) U.S. Cl. CPC H10K 59/38; H10K 59/122; H10K 59/40; H10K 59/873; H10K 2102/361

(57) ABSTRACT

Provided are a display panel and a display device. The display panel includes: a substrate layer and a touch electrode layer. Sub-pixel structures are disposed on a side of the substrate layer. The touch electrode layer includes a first electrode layer, a touch insulating layer, and a second electrode layer arranged in a stack. An orthographic projection of the second electrode layer on the substrate layer covers that of the touch insulating layer on the substrate layer. An edge of the orthographic projection of the second electrode layer on the substrate layer surrounds an edge of the orthographic projection of the touch insulating layer on the substrate layer; or an edge of the orthographic projection of the second electrode layer on the substrate layer at least partially overlaps with an edge of the orthographic projection of the touch insulating layer on the substrate layer.

### CROSS-REFERENCE TO RELATED APPLICATION(S)

This application is a Section 371 National Stage Application of International Application No. PCT/CN2024/096097 filed on May 29, 2024, which claims priority to Chinese Patent Application No. 202310729185.9 filed on Jun. 19, 2023, the whole contents of which are incorporated herein by reference in their entireties.

### TECHNICAL FIELD

The present disclosure relates to the field of display technologies, and in particular to a display panel and a display device.

### BACKGROUND

At present, with the continuous development of display technologies, OLEDs (Organic Light-Emitting Diodes) are being increasingly applied in flexible display technologies. Flexible OLED display panels may be used in foldable screens, rollable screens, and other display technologies that allow bending or folding. To reduce a thickness of a display panel, films that were originally attached externally may be integrated as internal films of a flexible display panel. To improve a display effect of a display panel, some optical film layers may be added inside the flexible display panel. However, as more film layers are integrated within the display panel, the number of high-temperature baking or other high-temperature process steps also increases, which tends to intensify stress concentration in some inorganic layers. Films with stress concentration are more prone to cracking under external forces, and when combined with the bending of film layers of the flexible display panel, a drop reliability of the display panel is significantly reduced, leading to lower product yield.

### SUMMARY

Provided are a display panel and a display device, which may improve the problem of stress concentration in the display panel, thereby improving the drop reliability of the display panel and improving the product yield.

In a first aspect of the present disclosure, a display panel is provided, including: a substrate layer, a plurality of sub-pixel structures are disposed on a side of the substrate layer; and a touch electrode layer disposed on a side of the sub-pixel structures away from the substrate layer, the touch electrode layer includes a plurality of first openings, and an orthographic projection of the first openings on the substrate layer covers an orthographic projection of the plurality of sub-pixel structures on the substrate layer. The touch electrode layer includes a first electrode layer, a touch insulating layer, and a second electrode layer arranged in a stack, the touch insulating layer is disposed between the first electrode layer and the second electrode layer, and the second electrode layer is disposed on a side of the touch insulating layer away from the substrate layer; and an orthographic projection of the second electrode layer on the substrate layer covers an orthographic projection of the touch insulating layer on the substrate layer, and an edge of the orthographic projection of the second electrode layer on the substrate layer surrounds an edge of the orthographic projection of the touch insulating layer on the substrate layer, or an edge of the orthographic projection of the second electrode layer on the substrate layer at least partially overlaps with an edge of the orthographic projection of the touch insulating layer on the substrate layer.

In combination with the first aspect of the present disclosure, in some embodiments, the orthographic projection of the touch insulating layer on the substrate layer covers an orthographic projection of the first electrode layer on the substrate layer, and the edge of the orthographic projection of the touch insulating layer on the substrate layer surrounds an edge of the orthographic projection of the first electrode layer on the substrate layer, or the edge of the orthographic projection of the touch insulating layer on the substrate layer at least partially overlaps with an edge of the orthographic projection of the first electrode layer on the substrate layer.

In combination with the first aspect of the present disclosure, in some embodiments, the orthographic projection of the second electrode layer on the substrate layer covers an orthographic projection of the first electrode layer on the substrate layer, and the edge of the orthographic projection of the second electrode layer on the substrate layer surrounds an edge of the orthographic projection of the first electrode layer on the substrate layer, or the edge of the orthographic projection of the second electrode layer on the substrate layer at least partially overlaps with an edge of the orthographic projection of the first electrode layer on the substrate layer.

In combination with the first aspect of the present disclosure, in some embodiments, the touch electrode layer includes a plurality of sensing regions, the touch insulating layer includes at least one bridging via in each sensing region, and the first electrode layer and the second electrode layer in a same sensing region are electrically connected through the at least one bridging via.

In combination with the first aspect of the present disclosure, in some embodiments, the display panel further includes: a cover insulating layer disposed on a side of the touch electrode layer away from the substrate layer; and a color filtering layer disposed on a side of the cover insulating layer away from the substrate layer. A thickness of the cover insulating layer is greater than or equal to 0, a material of the cover insulating layer includes an organic material, and a process temperature range for forming the cover insulating layer overlaps with a service process temperature range for the pixel structures.

In combination with the first aspect of the present disclosure, in some embodiments, the display panel further includes an encapsulation layer disposed between the sub-pixel structures and the touch electrode layer. The encapsulation layer includes a first inorganic layer, a first organic layer, and a second inorganic layer arranged in a stack, and the first organic layer is disposed between the first inorganic layer and the second inorganic layer; and a thickness of the first organic layer is less than or equal to 8 μm when the thickness of the cover insulating layer is greater than 0.

In combination with the first aspect of the present disclosure, in some embodiments, the thickness of the cover insulating layer is greater than or equal to 1 μm; and/or the thickness of the first organic layer is greater than or equal to 6 μm; and/or a process temperature for forming the cover insulating layer is less than or equal to 150° C.; and/or a service process temperature for the sub-pixel structures is less than or equal to 120° C.

In combination with the first aspect of the present disclosure, in some embodiments, the thickness of the cover insulating layer ranges from 1 μm to 3 μm; and/or the sub-pixel structures include a light-emitting layer, and a service process temperature for the light-emitting layer is less than or equal to 120° C.; and/or a baking process temperature for forming the cover insulating layer is less than or equal to 85° C.

In combination with the first aspect of the present disclosure, in some embodiments, the thickness of the cover insulating layer ranges from 1.2 μm to 1.5 μm; and/or a film layer elongation at break of the cover insulating layer is greater than or equal to 57‰; and/or an elongation at break of the organic material of the cover insulating layer is greater than 6%; and/or an adhesion of the color filtering layer on the cover insulating layer is greater than 5B, where B indicates that an adhesion test mode is cohesive failure; and/or a visible light transmittance of the cover insulating layer is greater than or equal to 95%.

In combination with the first aspect of the present disclosure, in some embodiments, the display panel further includes an organic planarization layer disposed on a side of the color filtering layer away from the substrate layer. A process temperature range for forming the organic planarization layer overlaps with the service process temperature range for the sub-pixel structures.

In combination with the first aspect of the present disclosure, in some embodiments, the color filtering layer includes a light-shielding layer, the light-shielding layer includes a plurality of second openings provided with color filtering films, an orthographic projection of the plurality of second openings on the substrate layer covers the orthographic projection of the sub-pixel structures on the substrate layer, and an orthographic projection of the light-shielding layer on the substrate layer covers an orthographic projection of the touch electrode layer on the substrate layer; and when the thickness of the cover insulating layer is equal to 0, the light-shielding layer is directly connected to the touch electrode layer and insulated from the touch electrode layer.

In combination with the first aspect of the present disclosure, in some embodiments, an insulating material is doped in the light-shielding layer, and the insulating material includes acrylic resin and/or epoxy resin.

In combination with the first aspect of the present disclosure, in some embodiments, an orthographic projection of each of the plurality of first openings on the substrate layer covers an orthographic projection of at least one of the plurality of second openings on the substrate layer.

In a second aspect of the present disclosure, a display device is provided, including the display panel as described in the first aspect of the present disclosure.

### BRIEF DESCRIPTION OF THE DRAWINGS

FIG. 1 shows a schematic partial structural diagram of a display panel according to some embodiments of the present disclosure;

FIG. 2 shows a schematic diagram of a partial pixel arrangement of a display panel according to some embodiments of the present disclosure;

FIG. 3 shows a schematic partial structural diagram of a display panel according to other embodiments of the present disclosure;

FIG. 4 shows a schematic structural diagram of a touch electrode layer according to some embodiments of the present disclosure;

FIG. 5 shows a schematic partial structural diagram of a display panel according to yet other embodiments of the present disclosure;

FIG. 6 shows a partial structural diagram of a sensing region of a display panel according to some embodiments of the present disclosure;

FIG. 7 shows a schematic partial structural diagram of a display panel according to still other embodiments of the present disclosure;

FIG. 8 shows a schematic partial structural diagram of a display panel according to further embodiments of the present disclosure; and

FIG. 9 shows a schematic structural diagram of a display device according to some embodiments of the present disclosure.

### DETAILED DESCRIPTION OF EMBODIMENTS

In order to better understand the technical solutions provided by the embodiments of the present disclosure, detailed descriptions of the technical solutions of the embodiments of the present disclosure are given below with reference to the accompanying drawings and specific embodiments. It should be understood that the embodiments of the present disclosure and specific features in the embodiments are provided as detailed descriptions of the technical solutions of the embodiments of the present disclosure, and are not intended to limit the technical solutions of the present disclosure. In case of no conflict, the embodiments of the present disclosure and the specific features in the embodiments may be combined with each other.

Herein, relational terms such as “first” and “second” are used merely to distinguish one entity or operation from another entity or operation, and do not necessarily require or imply any actual relationship or sequence between such entities or operations. Moreover, the terms “including”, “containing”, or any other variants thereof are intended to cover a non-exclusive inclusion, so that a process, method, article, or apparatus including a list of elements not only includes those elements, but may also include other elements not explicitly listed, or may include inherent elements of such process, method, article, or apparatus. Without further limitations, an element defined by the phrase “including a . . . ” does not exclude the presence of additional identical elements in the process, method, article, or apparatus including the element. The term “two or more” includes the case of two as well as more than two.

At present, with the continuous development of display technology, OLEDs are being increasingly applied in flexible display technologies. Flexible OLED display panels may be used in foldable screens, rollable screens, and other display technologies that allow bending or folding. To reduce a thickness of a display panel, films that were originally attached externally may be integrated as internal films of the flexible display panel. To improve a display effect of the display panel, some optical film layers may be added inside the flexible display panel. However, as more film layers are integrated within the display panel, the number of high-temperature baking or other high-temperature process steps also increases, which tends to intensify stress concentration in some inorganic layers. Films with stress concentration are more prone to cracking under external forces, and when combined with the bending of the film layers of the flexible display panel, a drop reliability of the display panel is significantly reduced, leading to lower product yield.

In view of this, some embodiments of the present disclosure provide a display panel and a display device, which may improve the problem of stress concentration in the display panel, thereby improving the drop reliability of the display panel and increasing the product yield.

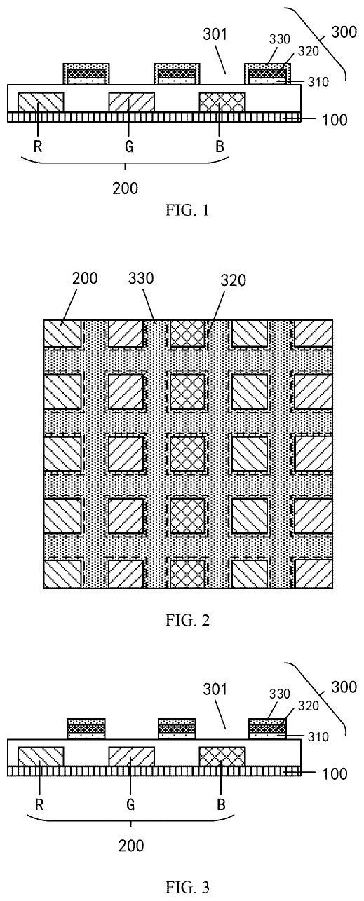

Some embodiments of the present disclosure provide a display panel. FIG. 1 shows a schematic partial structural diagram of a display panel according to some embodiments of the present disclosure. As shown in FIG. 1, the display panel includes a substrate layer 100, a plurality of sub-pixel structures 200, and a touch electrode layer 300. The plurality of sub-pixel structures 200 are disposed on a side of the substrate layer 100. The touch electrode layer 300 is disposed on a side of the sub-pixel structures 200 away from the substrate layer 100. The touch electrode layer 300 includes a plurality of first openings 301, and an orthographic projection of the first openings 301 on the substrate layer 100 covers an orthographic projection of the sub-pixel structures 200 on the substrate layer 100. That is, the touch electrode layer 300 needs to avoid light-emitting regions of the sub-pixel structures 200, and the first openings 301 are provided to avoid the sub-pixel structures 200. The touch electrode layer 300 includes a first electrode layer 310, a touch insulating layer 320, and a second electrode layer 330 arranged in a stack. The touch insulating layer 320 is disposed between the first electrode layer 310 and the second electrode layer 330, and the second electrode layer 330 is disposed on a side of the touch insulating layer 320 away from the substrate layer 100. An orthographic projection of the second electrode layer 330 on the substrate layer 100 covers an orthographic projection of the touch insulating layer 320 on the substrate layer 100. An edge of the orthographic projection of the second electrode layer 330 on the substrate layer 100 surrounds an edge of the orthographic projection of the touch insulating layer 320 on the substrate layer 100. In other words, the second electrode layer 330 entirely covers the touch insulating layer 320 on the side of the touch insulating layer 320 away from the substrate layer 100. One of the first electrode layer 310 and the second electrode layer 330 may serve as a transmitting electrode, and the other may serve as a receiving electrode. The transmitting electrode may be configured to transmit a sensing signal, and the receiving electrode may be configured to receive a sensing feedback signal. By analyzing the sensing signal and the sensing feedback signal, touch positioning may be obtained, thereby achieving a touch function.

In some embodiments, as shown in FIG. 1, the sub-pixel structures 200 may include a red sub-pixel R, a green sub-pixel G, and a blue sub-pixel B. It should be noted that the sub-pixel structures 200 shown in FIG. 1 are merely schematic and are not intended to specifically limit the embodiments of the present disclosure.

FIG. 2 shows a schematic diagram of a partial pixel arrangement of a display panel according to some embodiments of the present disclosure. As shown in FIG. 2, the dashed line indicates a boundary of the touch insulating layer 320, and the boundary of the touch insulating layer 320 is surrounded by a boundary of the second electrode layer 330. As shown in FIG. 1 and FIG. 2, a first opening 301 corresponds to a sub-pixel structure 200. It should be noted that, the pixel arrangement shown in FIG. 2 is merely schematic and is not intended to specifically limit the embodiments of the present disclosure. It should further be noted that for clarity of illustration, a size of the sub-pixel structures 200 shown in FIG. 1 and FIG. 2 has been reduced, while a size of the touch electrode layer 300 between the sub-pixel structures 200 has been enlarged. A size ratio between the touch electrode layer 300 and the sub-pixel structures 200 is merely schematic and is not intended to specifically limit the embodiments of the present disclosure.

FIG. 3 shows a schematic partial structural diagram of a display panel according to other embodiments of the present disclosure. As shown in FIG. 3, the edge of the orthographic projection of the second electrode layer 330 on the substrate layer 100 may at least partially overlap with the edge of the orthographic projection of the touch insulating layer 320 on the substrate layer 100. In other words, the edge of the second electrode layer 330 is at least partially flush with the edge of the touch insulating layer 320. In the embodiments shown in FIG. 3, the edge of the second electrode layer 330 is entirely flush with the edge of the touch insulating layer 320, thereby ensuring that the second electrode layer 330 fully covers the touch insulating layer 320.

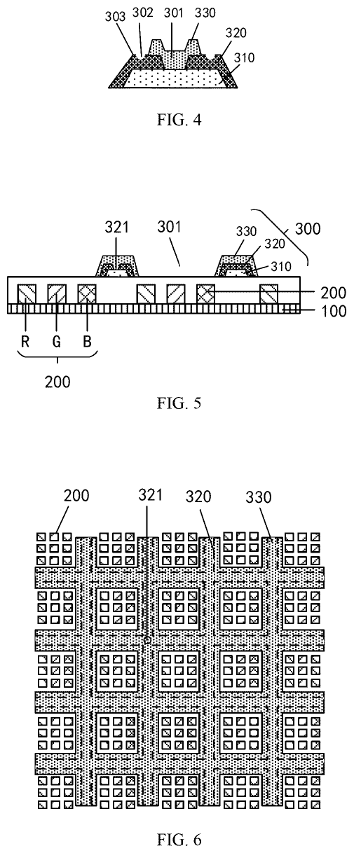

It should be noted that FIG. 4 shows a schematic structural diagram of a touch electrode layer according to some embodiments of the present disclosure. As shown in FIG. 4, the touch insulating layer 320 may cover the first electrode layer 310, and the second electrode layer 330 may partially cover the touch insulating layer 320, that is, the edge of the touch insulating layer 320 is exposed. During an etching process for patterning the second electrode layer 330, the edge of the touch insulating layer 320 exposed by the second electrode layer 330 may be corroded, which may be understood as an over-etching phenomenon, and a pit 302 may be formed. Since an edges of the pit 302 is close to the edge of the touch insulating layer 320, a local tip 303 may be formed. In a foldable display device or a curved display device assembled with a flexible display panel, due to the bending or folding of film layers, the local tip 303 may become stress concentration points during a drop. The stress concentration points may cause cracking in the film layers, or may cause cracking in overlying film layers, resulting in display defects. Thus, a reliability of the display panel is significantly reduced. In addition, a failure rate of drop tests in a product reliability test may increase, thereby reducing the product yield.

In view of the above problems, some embodiments of the present disclosure provide a display panel in which the second electrode layer 330 is disposed to cover the touch insulating layer 320, with the edge of the second electrode layer 330 covering the edge of the touch insulating layer 320, or with the edge of the second electrode layer 330 being partially flush with and partially covering the edge of the touch insulating layer 320, so as to avoid exposure of the edge of the touch insulating layer 320 relative to the second electrode layer 330. During the etching process for patterning the second electrode layer 330, such arrangement may prevent over-etching of the touch insulating layer 320, and thus avoid the formation of local tips at the exposed edge of the touch insulating layer 320. Therefore, the edge of the touch insulating layer 320 being covered or flush with the second electrode layer 330 may eliminate stress concentration tips caused by the formation of tips at the edge of the touch insulating layer 320, thereby improving the drop reliability of the display panel and increasing the yield of the display panel without changing types and number of film layers.

FIG. 5 shows a schematic partial structural diagram of a display panel according to yet other embodiments of the present disclosure. As shown in FIG. 5, the touch insulating layer 320 may include a bridging via 321, and the first electrode layer 310 and the second electrode layer 330 at two ends of the bridging via 321 may be electrically connected through the bridging via 321.

In some embodiments, the touch electrode layer 300 may include a plurality of sensing regions. The first electrode layer 310 within each sensing region is electrically connected, and the second electrode layer 330 within each sensing region is electrically connected. The first electrode layers 310 in adjacent sensing regions are insulated from each other, and the second electrode layers 330 in adjacent sensing regions are insulated from each other. Each sensing region may serve as a touch sensing unit, that is, each sensing region may serve as a touch sensor with a common transmitting electrode and a common receiving electrode.

FIG. 6 shows a partial structural diagram of a sensing region of a display panel according to some embodiments of the present disclosure. As shown in FIG. 6, the touch insulating layer 320 includes at least one bridging via 321 in each sensing region, and the first electrode layer 310 and the second electrode layer 330 within a same sensing region are electrically connected through at least one bridging via 321. When the first electrode layer 310 serves as a transmitting electrode and the second electrode layer 330 serves as a receiving electrode, a transmitted sensing signal may sequentially pass through the first electrode layer 310, the bridging via 321, and the second electrode layer 330, and then be transmitted to a sensing surface of the display panel. A touch sensing feedback signal may be transmitted through the second electrode layer 330 to a touch driving chip. By analyzing the touch sensing feedback signal in combination with the transmitted sensing signal, it may be determined whether a touch event has occurred at a corresponding position.

Referring to FIG. 5 and FIG. 6, in some embodiments, each first opening 301 corresponds to a plurality of sub-pixel structures 200. As shown in FIG. 6, each first opening 301 may correspond to nine sub-pixel structures 200. It should be noted that the number of sub-pixel structures 200 corresponding to each first opening 301 shown in FIG. 6 is merely schematic. In other embodiments, each first opening 301 may also correspond to three sub-pixel structures 200, six sub-pixel structures 200, twelve sub-pixel structures 200, or other numbers of sub-pixel structures 200, which is not specifically limited in the embodiments of the present disclosure.

As shown in FIG. 5, in some embodiments, the orthographic projection of the touch insulating layer 320 on the substrate layer 100 covers an orthographic projection of the first electrode layer 310 on the substrate layer 100, and the edge of the orthographic projection of the touch insulating layer 320 on the substrate layer 100 surrounds an edge of the orthographic projection of the first electrode layer 310 on the substrate layer 100.

Referring to FIG. 3, in other embodiments, the edge of the orthographic projection of the touch insulating layer 320 on the substrate layer 100 may at least partially overlap with the edge of the orthographic projection of the first electrode layer 310 on the substrate layer 100. The overlap between the edge of the touch insulating layer 320 and the edge of the first electrode layer 310 may ensure that the touch insulating layer 320 fully covers the first electrode layer 310, thereby ensuring an insulating effect of the touch insulating layer 320.

Referring to FIG. 5, in some embodiments, the orthographic projection of the second electrode layer 330 on the substrate layer 100 covers the orthographic projection of the first electrode layer 310 on the substrate layer 100, and the edge of the orthographic projection of the second electrode layer 330 on the substrate layer 100 surrounds the edge of the orthographic projection of the first electrode layer 310 on the substrate layer 100.

Referring to FIG. 3, in other embodiments, the edge of the orthographic projection of the second electrode layer 330 on the substrate layer 100 may at least partially overlap with the edge of the orthographic projection of the first electrode layer 310 on the substrate layer 100.

In some embodiments, both the first electrode layer 310 and the second electrode layer 330 may adopt a metal stacked structure of Ti (titanium)—Al (aluminum)—Ti (titanium), which is not specifically limited in the embodiments of the present disclosure. A thickness of Ti may range from 30 nm to 70 nm, for example, 37 nm, 45 nm, 50 nm, 53 nm, or 67 nm. A thickness of Al may range from 100 nm to 200 nm, for example, 120 nm, 150 nm, 160 nm, 170 nm, or 185 nm. In some embodiments, a thickness of the first electrode layer 310 may be 200 nm, and a thickness of the second electrode layer 330 may be 400 nm. The touch insulating layer 320 may include an inorganic material, such as silicon nitride. A thickness of the touch insulating layer 320 may range from 200 nm to 400 nm, for example, 150 nm, 230 mm, 310 nm, 370 nm, or 385 nm.

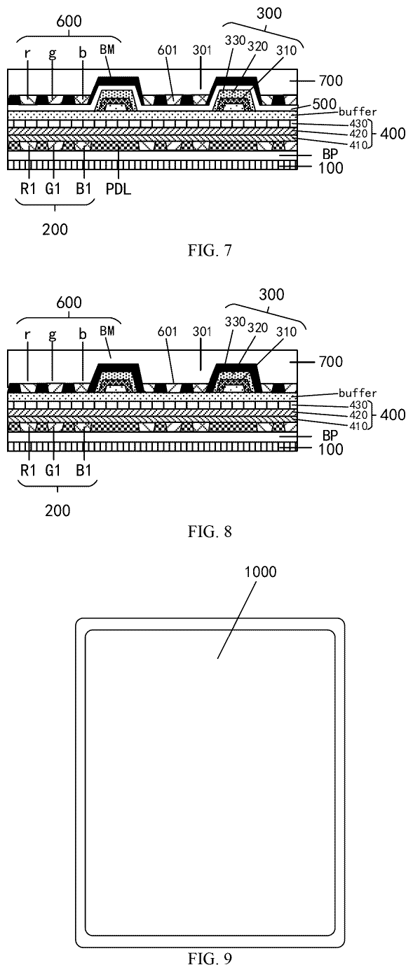

FIG. 7 shows a schematic partial structural diagram of a display panel according to still other embodiments of the present disclosure. As shown in FIG. 7, the display panel may further include a driving backplane BP, an encapsulation layer 400, a buffer insulating layer “buffer”, a cover insulating layer 500, a color filtering layer 600, and an organic planarization layer 700. The driving backplane BP is configured to drive the sub-pixel structures 200 to emit light. The sub-pixel structures 200 include a pixel defining layer PDL and a light-emitting layer. The light-emitting layer is disposed in openings of the pixel defining layer PDL. According to colors of the sub-pixel structures 200, the light-emitting layer includes a red light-emitting layer RI, a green light-emitting layer G1, and a blue light-emitting layer B1. For simplicity of illustration, anodes and cathodes in the sub-pixel structures 200 are not shown. The encapsulation layer 400 may protect the light-emitting layer. The color filtering layer 600 includes a light-shielding layer BM. The light-shielding layer BM includes a plurality of second openings 601, and color filtering films are disposed in the second openings 601. Correspond to the colors of the light-emitting layer, the color filtering films include a red filtering film r, a green filtering film g, and a blue filtering film b. An orthographic projection of the second openings 601 on the substrate layer 100 covers the orthographic projection of the sub-pixel structures 200 on the substrate layer 100, and an orthographic projection of the light-shielding layer BM on the substrate layer 100 covers the orthographic projection of the touch electrode layer 300 on the substrate layer 100. The first openings 301 may be in communication with the second openings 601. The first openings 301 and the second openings 601 may be arranged in a one-to-one manner, or the first openings 301 and the second openings 601 may be arranged in a one-to-many manner. FIG. 7 is merely schematic, and the embodiments of the present disclosure do not impose specific limitations.

In some embodiments, a thickness of the cover insulating layer 500 is greater than or equal to 0. When the thickness of the cover insulating layer 500 is equal to 0, it corresponds to a solution in which the cover insulating layer 500 is removed. When the thickness of the cover insulating layer 500 is greater than 0, it corresponds to a solution in which the cover insulating layer 500 is retained.

Referring to FIG. 7, the cover insulating layer 500 may be disposed on a side of the touch electrode layer 300 away from the substrate layer 100, and the color filtering layer 600 may be disposed on a side of the cover insulating layer 500 away from the substrate layer 100. A material of the cover insulating layer 500 includes an organic material, and a process temperature range for forming the cover insulating layer 500 overlaps with a service process temperature range for the sub-pixel structures 200.

It should be noted that in order to achieve a thinner and lighter display panel and to improve chromaticity, a color filtering layer solution may be adopted to replace the solution of externally attaching a polarizer. However, the color filtering layer solution requires adding five times of exposure, development and baking processes. Such processes may increase stress concentration in the cover insulating layer made of an inorganic material as well as in the inorganic layers disposed above the cover insulating layer. The stress concentration points may be intensively formed in the cover insulating layer, making the cover insulating layer a weak point for stress. Under external forces, cracking may occur in the cover insulating layer, leading to display defects and a poor drop reliability of the display panel.

In the display panel provided by some embodiments of the present disclosure, the cover insulating layer 500 is made of an organic material, which has a smaller elastic modulus than an inorganic material, so that stress concentration points will not accumulate in the cover insulating layer 500, thereby eliminating a stress concentration layer. By replacing the inorganic silicon nitride material with an organic film layer, the problem of high stress in inorganic thin films may be solved, thereby improving the reliability problem of film layer cracking caused by drop-induced stress concentration. In addition, the process for forming the cover insulating layer 500 made of an organic material involves some temperature settings. For example, the cover insulating layer 500 may be formed by coating and curing the organic material, and a curing temperature is typically higher than room temperature. Because the light-emitting layer in the sub-pixel structures 200 is generally not tolerant to high temperatures, it is required to form the cover insulating layer 500 using an organic material cured at a low temperature. Therefore, the process temperature range for forming the cover insulating layer 500 needs to overlap with a service process temperature range for the sub-pixel structures 200, and an overlapping temperature region may not only ensure successful preparation of the cover insulating layer 500, but also protect the sub-pixel structures 200 from being affected by the process temperature for forming the cover insulating layer 500.

Referring to FIG. 7, in some embodiments, the encapsulation layer 400 is disposed between the sub-pixel structures 200 and the touch electrode layer 300. The encapsulation layer 400 includes a first inorganic layer 410, a first organic layer 420, and a second inorganic layer 430 arranged in a stack, and the first organic layer 420 is disposed between the first inorganic layer 410 and the second inorganic layer 430. A thickness of the first organic layer 420 may be less than or equal to 8 μm, for example, 4 μm, 5 μm, 6 μm, or 7 μm. In some embodiments, the thickness of the first organic layer 420 may be greater than or equal to 6 μm, i.e., the thickness of the first organic layer 420 may range from 6 μm to 8 μm, such as 6 μm, 7 μm, or 8 μm.

A film layer formed from an organic material generally has a greater thickness than a film layer formed from an inorganic material, which may affect light transmittance. Therefore, it is possible to reduce the thickness of the first organic layer 420 of the encapsulation layer 400 to compensate for a light transmittance loss caused by the cover insulating layer 500. Typically, the thickness of the organic layer of the encapsulation layer ranges from 10 μm to 12 μm. In some embodiments of the present disclosure, the thickness of the first organic layer 420 of the encapsulation layer 400 may be reduced to 6 μm to 8 μm, such as 6.5 μm, 6.7 μm, 7.3 μm, or 7.6 μm, thereby improving the light transmittance and reducing the impact of the thickness of the cover insulating layer 500 on the light transmittance.

In some embodiments, the thickness of the cover insulating layer 500 may be greater than or equal to 1 μm. In other embodiments, the thickness of the cover insulating layer 500 may range from 1 μm to 3 μm. For example, the thickness of the cover insulating layer 500 may be 1 μm, 2 μm, or 3 μm. In still other embodiments, the thickness of the cover insulating layer 500 may range from 1.2 μm to 1.5 μm. For example, the thickness of the cover insulating layer 500 may be 1.2 μm, 1.3 μm, 1.35 μm, 1.4 μm, 1.45 μm, or 1.5 μm.

In some embodiments, a low-temperature OC (optical clear) material may be coated with a thickness of 1 μm to 1.5 μm on a side of the touch electrode layer 300 away from the substrate layer 100. After exposure and development, baking is performed at 85° C. for 1 hour to obtain the cover insulating layer 500. It should be noted that, vacuuming or pre-baking is performed on a negative photoresist of thermally curable OC, followed by exposure, development, and post-baking (the post-baking temperature may range from 85° C. to 150° C.). The following reliability tests may be further performed: erosion by acids, alkalis, solvents, stripping solutions, and copper etchants with concentrations within 5%; resistance to oxygen ICP dry etching; resistance to metal deposition at 25° C.~100° C.; and exposure to a high-humidity environment at 100° C./85%; a sheet resistance remains stable in a range of 5.0E×10¹²~10¹⁴ ohms, with a light transmittance of 99%.

In some embodiments, the process temperature for forming the cover insulating layer 500 may be less than or equal to 150° C., for example, 85° C. to 150° C., such as 85° C., 100° C., or 150° C. The service process temperature for the sub-pixel structures is less than or equal to 120° C. A service process temperature for the light-emitting layer is less than or equal to 120° C.

In some embodiments, the baking process temperature for forming the cover insulating layer 500 is less than or equal to 85° C.

In some embodiments, a film layer elongation at break of the cover insulating layer 500 is greater than or equal to 57% s, for example, 57.4% 0, 60% %, or 65% %. The cover insulating layer 500 may pass drop tests for the display panel.

In some embodiments, an elongation at break of the organic material for forming the cover insulating layer 500 may be greater than 6%.

In some embodiments, an adhesion of the color filtering layer 600 on the cover insulating layer 500 is greater than 5B. It should be noted that, the adhesion is measured by applying a vertical and uniform tensile force at a specified speed on a bonding surface of a sample, so as to determine a force required to cause failure of adhesion between coatings or between a coating and a substrate, expressed in N/cm². The adhesion is calculated by dividing a load value at failure of the sample by a cross-sectional area of a coated column to be tested. The failure forms include: adhesion failure represented by A; cohesive failure represented by B; adhesive self-failure or rupture of a topcoat portion of the tested coating represented by C. If two or more failure forms occur, an area percentage of each failure form should be specified, and more than 70% is valid. An adhesion being greater than 5B indicates that the failure form of the adhesion test is cohesive failure, and the applied force at the failure is greater than 5 N/cm².

In some embodiments, a visible light transmittance of the cover insulating layer 500 is greater than or equal to 95%.

In some embodiments, the organic planarization layer 700 is disposed on a side of the color filtering layer 600 away from the substrate layer 100. A process temperature range for forming the organic planarization layer 700 overlaps with a service process temperature range for the sub-pixel structures.

FIG. 8 shows a schematic partial structural diagram of a display panel according to further embodiments of the present disclosure. Different from FIG. 7, FIG. 8 shows that the cover insulating layer 500 is removed from between the touch electrode layer 300 and the color filtering layer 600, that is, the thickness of the cover insulating layer 500 is equal to 0, and the light-shielding layer BM is directly connected to the touch electrode layer 300. The light-shielding layer BM and the touch electrode layer 300 are insulated from each other, so as to prevent the light-shielding layer BM from conducting charges from other external film layers into the touch electrode layer 300, thereby avoiding interference with the change of induced charges on the touch electrode layer 300, and ensuring a touch accuracy of the touch electrode layer 300.

In some embodiments, an insulating material may be doped in the light-shielding layer BM. For example, the light-shielding layer BM may be doped with acrylic resin and/or epoxy resin.

In some embodiments, a light-shielding material may be coated first with a thickness of 1 μm to 1.5 μm, followed by exposure and development, and then baked at 85° C. for 1 hour to form the light-shielding layer BM.

After the light-shielding layer BM is formed, the color filtering film may be provided, with a thickness ranging from 1 μm to 1.5 μm, which is then subjected to exposure and development, followed by baking at 85° C. for 1 hour, thereby forming a pattern for the color filtering film.

After the formation of the color filtering film is completed, an organic planarization material may be coated with a thickness of 2.5 μm to 5 μm, which is then subjected to exposure, development, and baking at 85° C. for 1 hour to form a pattern of the organic planarization layer 700. It should be noted that, the organic planarization layer 700 may be made of the same organic material as the cover insulating layer 500. The organic material has excellent fluidity, and after film formation and leveling, it may effectively cover an uneven morphology of an underlying layer. In addition, the organic film may also passivate metal sharp corners and provide an effective coverage.

In the display panel provided by some embodiments of the present disclosure, by doping an insulating material in the light-shielding layer BM, it is not needed to provide an additional cover insulating layer, which simplifies a film layer configuration of the display panel while ensuring that the touch electrode layer 300 remains in an insulated environment. Removing the cover insulating layer 500 may not only eliminate the stress concentration problem caused by the inorganic insulating layer, but also improve the light transmittance.

The present disclosure further provides a display device in some embodiments. FIG. 9 shows a schematic structural diagram of a display device according to some embodiments of the present disclosure. As shown in FIG. 9, the display device may include a display panel 1000 provided in any of the embodiments described above.

It should be noted that the display device provided by some embodiments of the present disclosure may include a smart phone, a tablet computer, a notebook computer, a television, a smart wearable apparatus, or the like. The smart wearable apparatus may include a smart watch, an AR (augmented reality) device, a VR (virtual reality) device, or the like.

In the display device provided by some embodiments of the present disclosure, the second electrode layer 330 of the touch electrode layer 300 in the display panel 1000 is disposed to cover the touch insulating layer 320, with the edge of the second electrode layer 330 covering the edge of the touch insulating layer 320, or with the edge of the second electrode layer 330 being partially flush with and partially covering the edge of the touch insulating layer 320, which may avoid exposure of the edge of the touch insulating layer 320 relative to the edge of the second electrode layer 330. During the etching process for patterning the second electrode layer 330, over-etching of the touch insulating layer 320 may be avoided, thereby preventing formation of local tips at the exposed edge of the touch insulating layer 320. Therefore, when the edge of the touch insulating layer 320 is covered by or flush with the edge of the second electrode layer 330, stress concentration points caused by formation of tips at the edge of the touch insulating layer 320 may be eliminated, thereby improving the drop reliability of the display panel and increasing the yield of the display panel without changing the types and number of film layers.

It should be noted that in the above embodiments, each embodiment has its own focus of description. For portions not described in detail in a particular embodiment, reference may be made to the relevant descriptions in other embodiments.

The above embodiments are provided to illustrate the technical solutions of the present disclosure, and are not intended to limit the present disclosure. Although the present disclosure has been described in detail with reference to the foregoing embodiments, those of ordinary skill in the art should understand that: modifications may still be made to the technical solutions described in the foregoing embodiments, or equivalent substitutions may be made to some of the technical features. Such modifications or substitutions do not cause the essence of the corresponding technical solutions to depart from the spirit and scope of the technical solutions of the embodiments of the present disclosure.

Although some embodiments of the present disclosure have been described, those skilled in the art may make additional changes and modifications to these embodiments once the basic inventive concept is obtained. Accordingly, the appended claims are intended to be construed as including the embodiments described above as well as all changes and modifications that fall within the scope of the present disclosure.

Obviously, those skilled in the art may make various modifications and variations to the present disclosure without departing from the spirit and scope of the present disclosure. In such case, if these modifications and variations of the present disclosure fall within the scope of the claims of the present disclosure and their equivalent technologies, the present disclosure is also intended to include these modifications and variations.

1. A display panel, comprising:
a substrate layer, wherein a plurality of sub-pixel structures are disposed on a side of the substrate layer; and
a touch electrode layer disposed on a side of the sub-pixel structures away from the substrate layer, wherein the touch electrode layer comprises a plurality of first openings, and an orthographic projection of the first openings on the substrate layer covers an orthographic projection of the plurality of sub-pixel structures on the substrate layer;
wherein,
the touch electrode layer comprises a first electrode layer, a touch insulating layer, and a second electrode layer arranged in a stack, the touch insulating layer is disposed between the first electrode layer and the second electrode layer, and the second electrode layer is disposed on a side of the touch insulating layer away from the substrate layer; and
an orthographic projection of the second electrode layer on the substrate layer covers an orthographic projection of the touch insulating layer on the substrate layer, and an edge of the orthographic projection of the second electrode layer on the substrate layer surrounds an edge of the orthographic projection of the touch insulating layer on the substrate layer, or an edge of the orthographic projection of the second electrode layer on the substrate layer at least partially overlaps with an edge of the orthographic projection of the touch insulating layer on the substrate layer.

2. The display panel of claim 1, wherein the orthographic projection of the touch insulating layer on the substrate layer covers an orthographic projection of the first electrode layer on the substrate layer, and the edge of the orthographic projection of the touch insulating layer on the substrate layer surrounds an edge of the orthographic projection of the first electrode layer on the substrate layer, or the edge of the orthographic projection of the touch insulating layer on the substrate layer at least partially overlaps with an edge of the orthographic projection of the first electrode layer on the substrate layer.

3. The display panel of claim 1, wherein the orthographic projection of the second electrode layer on the substrate layer covers an orthographic projection of the first electrode layer on the substrate layer, and the edge of the orthographic projection of the second electrode layer on the substrate layer surrounds an edge of the orthographic projection of the first electrode layer on the substrate layer, or the edge of the orthographic projection of the second electrode layer on the substrate layer at least partially overlaps with an edge of the orthographic projection of the first electrode layer on the substrate layer.

4. The display panel of claim 1, wherein the touch electrode layer comprises a plurality of sensing regions, the touch insulating layer comprises at least one bridging via in each sensing region, and the first electrode layer and the second electrode layer in a same sensing region are electrically connected through the at least one bridging via.

5. The display panel of claim 1, further comprising:
a cover insulating layer disposed on a side of the touch electrode layer away from the substrate layer; and
a color filtering layer disposed on a side of the cover insulating layer away from the substrate layer,
wherein a thickness of the cover insulating layer is greater than or equal to 0, a material of the cover insulating layer comprises an organic material, and a process temperature range for forming the cover insulating layer overlaps with a service process temperature range for the sub-pixel structures.

6. The display panel of claim 5, further comprising an encapsulation layer disposed between the sub-pixel structures and the touch electrode layer,
wherein,
the encapsulation layer comprises a first inorganic layer, a first organic layer, and a second inorganic layer arranged in a stack, and the first organic layer is disposed between the first inorganic layer and the second inorganic layer; and
a thickness of the first organic layer is less than or equal to 8 μm when the thickness of the cover insulating layer is greater than 0.

7. The display panel of claim 6, wherein,
the thickness of the cover insulating layer is greater than or equal to 1 μm; and/or
the thickness of the first organic layer is greater than or equal to 6 μm; and/or
a process temperature for forming the cover insulating layer is less than or equal to 150° C.; and/or
a service process temperature for the sub-pixel structures is less than or equal to 120° C.

8. The display panel of claim 7, wherein,
the thickness of the cover insulating layer ranges from 1 μm to 3 μm; and/or
the sub-pixel structures comprise a light-emitting layer, and a service process temperature for the light-emitting layer is less than or equal to 120° C.; and/or
a baking process temperature for forming the cover insulating layer is less than or equal to 85° C.

9. The display panel of claim 8, wherein,
the thickness of the cover insulating layer ranges from 1.2 μm to 1.5 μm; and/or
a film layer elongation at break of the cover insulating layer is greater than or equal to 57% %; and/or
an elongation at break of the organic material of the cover insulating layer is greater than 6%; and/or
an adhesion of the color filtering layer on the cover insulating layer is greater than 5B, where B indicates that an adhesion test mode is cohesive failure; and/or
a visible light transmittance of the cover insulating layer is greater than or equal to 95%.

10. The display panel of claim 5, further comprising an organic planarization layer disposed on a side of the color filtering layer away from the substrate layer,
wherein a process temperature range for forming the organic planarization layer overlaps with the service process temperature range for the sub-pixel structures.

11. The display panel of claim 5, wherein,
the color filtering layer comprises a light-shielding layer, the light-shielding layer comprises a plurality of second openings provided with color filtering films, an orthographic projection of the plurality of second openings on the substrate layer covers the orthographic projection of the sub-pixel structures on the substrate layer, and an orthographic projection of the light-shielding layer on the substrate layer covers an orthographic projection of the touch electrode layer on the substrate layer; and
when the thickness of the cover insulating layer is equal to 0, the light-shielding layer is directly connected to the touch electrode layer and insulated from the touch electrode layer.

12. The display panel of claim 11, wherein an insulating material is doped in the light-shielding layer, and the insulating material comprises acrylic resin and/or epoxy resin.

13. The display panel of claim 11, wherein an orthographic projection of each of the plurality of first openings on the substrate layer covers an orthographic projection of at least one of the plurality of second openings on the substrate layer.

14. A display device, comprising the display panel of claim 1.

15. The display panel of claim 8, wherein the sub-pixel structures further comprise a pixel defining layer, wherein the light-emitting layer is disposed in an opening of the pixel defining layer.

16. The display panel of claim 1, further comprising a driving backplane disposed between the substrate layer and the plurality of sub-pixel structures.

17. The display panel of claim 6, further comprising a buffer insulating layer disposed between the encapsulation layer and the touch electrode layer.

18. The display panel of claim 10, wherein the organic planarization layer and the cover insulating layer comprise a same organic material.

19. The display panel of claim 1, wherein each of the first electrode layer and the second electrode layer comprises a metal stacked structure of Ti—Al—Ti.

20. The display panel of claim 19, wherein a thickness of Ti ranges from 30 nm to 70 nm, and a thickness of Al ranges from 100 mm to 200 nm.
